(19) United States
(12) Patent Application Publication
(10) Pub. No.: US 2021/0234132 A1
(43) Pub. Date: Jul. 29, 2021

(54) Shaped Filler Material In a QLED/OLED Pixel

(71) Applicant: Sharp Kabushiki Kaisha, Osaka (JP)

(72) Inventor: David James Montgomery, Oxford (GB)

(21) Appl. No.: 16/775,600

(22) Filed: Jan. 29, 2020

(51) Int. Cl. H01L 51/52; H01L 51/50

(52) U.S. Cl. CPC H01L 51/5275; H01L 51/5253; H01L 51/502

(57) ABSTRACT

A light-emitting device has enhanced light output by shaping as non-planar an emitting side surface of the filler material layer to improve light extraction. The light-emitting device includes a bank structure; an emissive cavity disposed within the bank structure; and a filler material layer disposed within the bank structure and on a light-emitting side of the emissive cavity. An emitting side surface of the filler material layer opposite from the emissive cavity is a non-planar emitting side surface. The emitting side surface is shaped such that the filler material layer includes a first region of positive curvature and a second region of negative curvature. The second region of negative curvature may be located adjacent to the bank structure, and the first region of positive curvature may be located centrally relative to the second region of negative curvature. The first region of positive curvature may be configured as a single element of positive curvature, or as a plurality of positive curvature elements such as a micro-lens array or a prism array.

### TECHNICAL FIELD

The present application relates to a layer and bank structure used for an emissive device, in particular for a quantum dot light-emitting diode (QLED) or organic light-emitting diode (OLED) for a display device. In particular, embodiments of the present application improve efficiency, reduce color shift, and improve brightness for top-emitting light-emitting device structures embedded in a high refractive index encapsulate material surrounded by a bank structure.

### BACKGROUND ART

There are a number of conventional configurations of organic light-emitting diode (OLED) and quantum dot light-emitting diode (QLED) structures that include optical cavities in the LED structure to generate a cavity effect for extraction of light. For example, US 2006/0158098 (Raychaudhuri et al., published Jul. 20, 2006) describes a top emitting structure, and U.S. Pat. No. 9,583,727 (Cho et al., issued Feb. 28, 2017) describes an OLED and QLED structure with light-emitting regions between reflective areas, one of which is partially transmitting to emit light. Methods for improving the luminance of such optical cavities, for example US 2015/0084012 (Kim et al., published Mar. 26, 2015), include the use of dispersive layers in an OLED structure. Other examples include U.S. Pat. No. 8,894,243 (Cho et al., issued Nov. 25, 2014), which describes the use of microstructure scattering for improving efficiency, and WO 2017/205174 (Freier et al., published Nov. 30, 2017), which describes enhancement of the light emission by use of surface plasmon nanoparticles or nanostructures in the charge transport layers.

Methods such as referenced above that involve modifications to the cavity structure are often difficult to implement, as such methods require very small size features or precise control of layers. One alternative to modifying the cavity is to use a thick top “filler” layer with a relatively high refractive index, which enables Fresnel reflections to be reduced and transmissivity through a top electrode to be increased. The light traveling through the high refractive index layer, however, largely will be trapped by total internal reflection (TIR). To extract light that encounters TIR, reflective and/or scattering bank structures often are used surrounding the filler layer to out-couple light that otherwise would be trapped by TIR.

CN 106876566 (Chen et al., published Jun. 20, 2017) and U.S. Pat. No. 9,029,843 (Harada et al., issued May 12, 2015) describe such a pixel arrangement with banks and a filler material above the organic layers of the cavity and between the banks. U.S. Pat. No. 7,091,658 (Ito et al., issued Aug. 15, 2006) describes banks that can be reflective using an electrode metallic material, and KR 102015002014 (Cambridge Display Tech) describes banks that can be shaped in different structures using different assembly steps. U.S. Pat. No. 10,090,489 (Uchida et al., issued Oct. 2, 2018) describes a shaped reflector underneath the organic layers. A particular filler layer structure also can be selected, such as described for example in U.S. Pat. No. 8,207,668 (Cok et al., issued Jun. 26, 2012), in which the fillers and organic layers have different thicknesses for different sub-pixels to maximize the light output as a function of wavelength.

Control of the organic layer output also can be achieved by appropriate material choices (e.g. lyophilic/Lyophobic) or other structural modifications. For example, U.S. Pat. No. 7,902,750 (Takei et al., issued Mar. 8, 2011) describes cavity layers that are curved and the encapsulation layer is a planarizing layer, and U.S. Pat. No. 9,312,519 (Yamamoto, issued Apr. 12, 2016) describes organic layers that are both convex and concave in orthogonal directions.

### SUMMARY OF INVENTION

Embodiments of the present application pertain to designs for an emissive display including light-emitting devices, such as a quantum dot electro-emissive material, in an LED arrangement. This arrangement typically includes a layer of a quantum dot (QD) emissive material sandwiched between multiple charge transport layers (CTLs), including an electron transport layer (ETL) and a hole transport layer (HTL). This stack is then sandwiched between two conducting electrode layers, one side of which is grown on a glass substrate. Embodiments of the present application specifically relate to “top emitting” (TE) structures, in which light emission is from the side of the device stack opposite from the glass substrate layer.

As referenced above, prior attempts to enhance light output of such devices often have focused on modifying the structure of the optical cavity that includes the emissive layer and the charge transport layers. Such attempts, however, have not addressed the problem of total internal reflection (TIR) experienced by a significant portion of light due to the high refractive index of the filler encapsulation layer that is above the optical cavity. In conventional configurations, the light subjected to TIR essentially is lost.

Embodiments of the present application improve light output by reconfiguring the encapsulation filler material layer as compared to conventional configurations to improve light extraction of light that otherwise would be lost due to TIR. In embodiments of the present application, a shape of a top (emitting side) surface of the filler material layer is modified to be non-planar, such as for example an asymmetric spherical curve or as multiple lens-lets. The shape may be dependent on the emission pattern of the QLED or other light-emitting device. An indentation optionally may be provided in the filler material layer near the bank structure to increase extraction from bank reflection. Advantages of embodiments of the present application include increased light extraction from the light-emitting device and higher tolerance for the design of the optical cavity.

An aspect of the invention, therefore, is a light-emitting device that has enhanced light output by shaping as non-planar an emitting side surface of the filler material layer to improve light extraction. In exemplary embodiments, the light-emitting device includes a bank structure; an emissive cavity disposed within the bank structure; and a filler material layer disposed within the bank structure and on a light-emitting side of the emissive cavity. An emitting side surface of the filler material layer opposite from the emissive cavity is a non-planar emitting side surface.

In exemplary embodiments, the emitting side surface is shaped such that the filler material layer includes a first region of positive curvature and a second region of negative curvature. The second region of negative curvature may be located adjacent to the bank structure, and the first region of positive curvature may be located centrally relative to the second region of negative curvature. The first region of positive curvature may be configured as a single element of positive curvature, or as a plurality of positive curvature elements such as a micro-lens array or a prism array. The emissive cavity is disposed on a substrate, and the emissive cavity may be a top emitting device that emits light in a direction opposite from the substrate.

To the accomplishment of the foregoing and related ends, the invention, then, comprises the features hereinafter fully described and particularly pointed out in the claims. The following description and the annexed drawings set forth in detail certain illustrative embodiments of the invention. These embodiments are indicative, however, of but a few of the various ways in which the principles of the invention may be employed. Other objects, advantages and novel features of the invention will become apparent from the following detailed description of the invention when considered in conjunction with the drawings.

### BRIEF DESCRIPTION OF DRAWINGS

FIG. 1 is a drawing depicting an example of a conventional cavity structure for a top emitting light-emitting device.

FIG. 2 is a drawing depicting an example of a conventional light-emitting device structure for a pixel that includes the cavity structure of FIG. 1.

FIG. 3 is a drawing depicting an exemplary light-emitting device structure for a pixel in accordance with embodiments of the present application.

FIG. 4 is a drawing depicting the effect of the configuration of the filler material layer of FIG. 3 on light emission from the light-emitting device.

FIG. 5 is a drawing depicting another exemplary light-emitting device structure for a pixel in accordance with embodiments of the present application, using a micro-lens array as a region of positive curvature.

FIG. 6 is a drawing depicting another exemplary light-emitting device structure for a pixel in accordance with embodiments of the present application, using a triangular prism array as a region of positive curvature.

### DESCRIPTION OF EMBODIMENTS

Embodiments of the present application will now be described with reference to the drawings, wherein like reference numerals are used to refer to like elements throughout. It will be understood that the figures are not necessarily to scale.

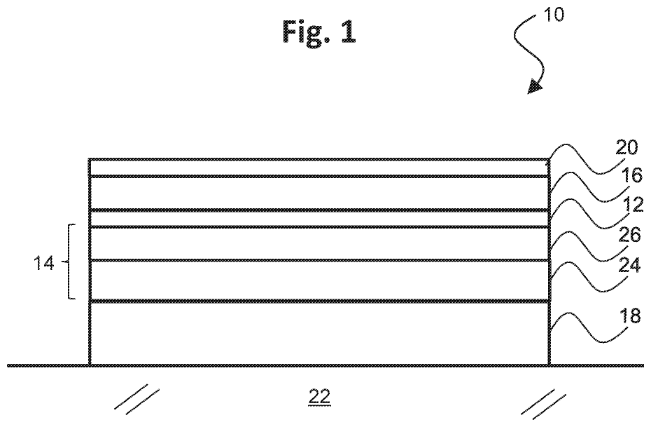

FIG. 1 is a drawing depicting an example of a conventional cavity structure 10 for a top emitting light-emitting device. Embodiments of the present application pertain to designs for an emissive display involving a quantum dot electro-emissive material in an LED arrangement (QLED). Although the description largely is in the context of QLED light-emitting devices, principles of the present application are not limited to such devices and also are applicable to other types of light-emitting devices, such as for example organic light-emitting (OLED) devices. Accordingly, for purposes of this application description as to QLED devices applies equally to OLED devices (unless otherwise stated specifically), and vice versa.

A top-emitting arrangement such as corresponding to the light-emitting device 10 includes an emissive layer 12 that includes a quantum dot (QD) or other suitable emissive material. The emissive layer 12 is sandwiched between multiple charge transport layers (CTLs), including a hole transport layer (HTL) 14 and an electron transport layer (ETL) 16. This stack is then sandwiched between first and second conducting electrode layers 18 and 20, one side of which is grown on a glass substrate 22. Embodiments of the present application specifically relate to “top emitting” (TE) structures, in which light emission is from the side of the device stack opposite from the glass substrate layer. Substrate materials may be used other than glass, such as for example various plastic materials (e.g., polyimide, polycarbonate or polymethyl methacrylate for example).

In the example of FIG. 1, based on typical fabrication processes for TE devices such as the light-emitting device 10, in one exemplary structure the first conducting electrode layer 18 is a relatively thick layer, e.g. greater than 80 nm, which may be a metal layer such as silver or aluminium, deposited on the glass substrate 22. A further layer of another conducting metallic or non-metallic (e.g. indium tin oxide (ITO)) material may be added on the metal layer as part of the first conducting layer 18. An HTL layer 14 is deposited on the thick conducting electrode layer 18. In a TE device, the thick conductive layer 18 is reflective to direct light toward the top of the stack for light emission opposite from the substrate side. The ETL side second conducting electrode layer 20 is a relatively thin metal layer as compared to the HTL side conducting electrode layer 18. The second electrode layer 20, therefore, is thick enough to carry sufficient current, but thin enough to be transparent to the light emission. Suitable materials for the second electrode layer 20 include silver or a magnesium-silver alloy.

A typical ETL layer 16 material includes Zinc Oxide (ZnO) nanoparticles, and a typical HTL layer 14 is a dual layer including a first HTL component layer 24 of PEDOT:PSS (poly(3,4-ethylenedioxythiophene) polystyrene sulfonate) deposited on the reflective first electrode layer 18, and a second HTL component layer 26 of TFB [poly(9,9′-dioctylfluorene-co-bis-N,N′-(4-butylphenyl)diphenylamine)] located between the PEDOT layer 24 and the emissive layer 12. It will appreciated that the ETL and HTL layers can be reversed with the ETL on the substrate side and the HTL on the non-substrate side relative to the emissive layer 12, and the principles of the present application also apply to such an inverted structure as well. Accordingly, the ETL and HTL more generally may be referred to as charge transport layers (CTLs).

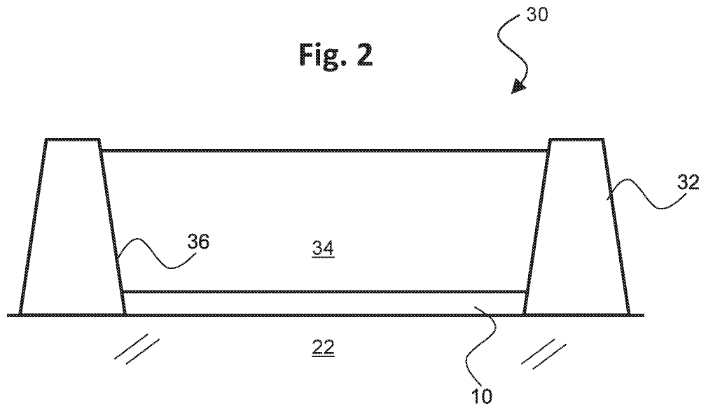

FIG. 2 is a drawing depicting an example of a conventional light-emitting device structure 30 for a pixel that includes the cavity structure 10 of FIG. 1. The exemplary pixel structure 30 includes the emissive cavity layers 10 deposited on the substrate 22 and confined within a bank structure 32 that is disposed around or about a perimeter of the emissive cavity and constitutes a barrier of the pixel 30 on the substrate relative to adjacent pixels. The space above the emissive cavity layers 10 within the bank structure 32 is filled with a filler or encapsulate material layer 34 used to protect the emissive cavity layer 10. The filler material layer 34 also extracts light from the emissive cavity to a greater extent than air would do, due to a higher refractive index. Light trapped in the emissive cavity layers 10 is quickly absorbed, but light trapped in the thicker filler layer 34 has the chance to propagate to the bank edges and can be extracted from the pixel by reflection off of the bank structure. The bank structure 32 may or may not be opaque and the bank surface towards the filler material can be scattering or specular reflective by providing a coating. Above the filler layer 34 is typically air or a low refractive index material to prevent light from leaking into the neighbouring pixels and creating cross-talk.

More specifically, in QLED or OLED pixels or sub-pixels exemplified in FIG. 2 by the light-emitting device 30, the cavity structure 10 is enclosed within a bank structure 32 that is positioned adjacent to a filler material 34 of a relatively high refractive index of typically above 1.5 (e.g., 1.5-2.5). The thickness of the bank structure 32 in a direction perpendicular to the cavity structure 10 tends to be about 1-10 microns and will depend upon the desired thickness of the filler material layer in said direction perpendicular to the cavity structure 10. In the depiction of FIG. 2, the bank structure 32 extends above the filler material layer 34 in the emitting side direction, but the thickness of the bank structure 32 alternatively may be equal to or less than the thickness of the filter material 34 in the emitting side direction.

The bank structure 32 may be formed of a photoresist material, such as polyimide, grown on the glass substrate 22 to form barriers that separate adjacent pixels, and has a scattering or specular reflective inner surface 36 facing the filler material layer 34. For example, the bank structure inner surface 36 that faces towards the filler material layer 34 may be made reflective by extending the second (top) electrode layer 20 over the bank structure 32 along the surface 36, or by depositing a comparable metal layer on said surface. The filler material 34 may be made of any suitable high-refractive index material, i.e., having a refractive index generally above 1.5 and typically 1.5-2.5. A typical way to form patternable high refractive index materials for the filler material is: monomer(s)+high refractive index inorganic nanoparticle+photoinitiator (optional). The monomers may be a -thiol plus another group, for example an -ene or an -yne, or other suitable polymers. The high refractive index nanoparticles may be oxide nanoparticles, such as for example titanium oxide (TiO₂) and zinc oxide (ZnO). Parylene C [a.k.a. poly(p-xylylene)] has been used as an OLED encapsulant.

The higher refractive index filler material 34 extracts more light from the emissive cavity 10 than if air were directly above the emissive cavity 10. An air gap (or other suitable low refractive index layer) is present over the filler material 34 to prevent optical crosstalk by preventing light from being coupled in a top glass substrate layer (not shown in FIG. 2) to the neighboring pixels. This air gap does trap light in the filler material which is more readily absorbed. A purpose of embodiments of the present application is to extract light more effectively from the filler material 34 without coupling the extracted light into the upper glass substrate layer and then to neighboring pixels.

As referenced above, prior attempts to enhance light output of such devices often have focused on modifying the structure of the optical cavity that includes the emissive layer and the charge transport layers. Such attempts, however, have not addressed the problem of total internal reflection (TIR) experienced by a significant portion of light due to the high refractive index of the filler encapsulation layer that is above the optical cavity. In conventional configurations, the light subjected to TIR essentially is lost. Embodiments of the present application improve light output by reconfiguring the encapsulation layer as compared to conventional configurations to improve light extraction of light that otherwise would be lost due to TIR. In embodiments of the present application, a shape of the top, i.e. emitting side, surface of the filler material layer is modified to be non-planar, such as an asymmetric spherical curve or as multiple lens-lets. The precise shape may be dependent upon the emission pattern of the QLED or other light-emitting device. An indentation optionally may be provided in the filler material layer near the bank structure to increase extraction from bank reflection or scattering. Advantages of embodiments of the present application include increased extraction from the light-emitting device and higher tolerance for the design of the emissive cavity.

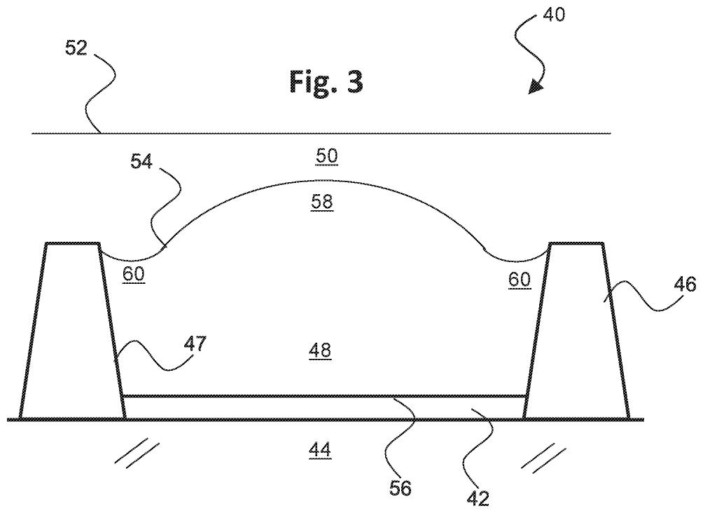

FIG. 3 is a drawing depicting an exemplary light-emitting device structure 40 for a pixel in accordance with embodiments of the present application. Similarly as in the conventional structure of FIG. 2, the exemplary pixel structure 40 includes an emissive cavity 42 disposed on a substrate 44 and disposed within a bank structure 46 that is positioned around or about the emissive cavity and constitutes a barrier of the pixel 40 on the substrate relative to adjacent pixels. The emissive cavity 42 may be configured in any suitable manner as is known in the art, such as described above for example in connection with FIG. 1. In exemplary embodiments, the emissive cavity 42 is a top emitting device that emits light in a direction opposite from the substrate 44.

The space above the emissive cavity 42 within the bank structure 46 is filled with a filler or encapsulate material layer 48 used to protect the emissive cavity 42. Accordingly, the filler material layer 48 is disposed within the bank structure 46 and on a light-emitting side of the emissive cavity 42. As detailed above, the filler material layer 48 also extracts light from the emissive cavity 42 to a greater extent than air would do, due to a higher refractive index. The bank structure 46 is typically opaque and has an inner surface 47 that faces the filler material layer 48 that can be scattering or specular reflective by providing a suitable coating, or by extending an electrode layer along the bank structure, as described above. Above the filler material layer 48 is typically a low refractive index planarizing material layer 50, which may air or an aero-gel, or other suitable low refractive index material having a refractive index of about 1.0-1.2. Examples may include siloxane based nano-composite polymers, which have a refractive index as low as 1.15. Other examples of the low refractive index material layer 50 may include Poly(1,1,1,3,3,3-hexafluoroisopropyl acrylate) with a refractive index of 1.375, and Poly(2,2,3,3,4,4,4-heptafluorobutyl acrylate) with a refractive index of 1.377. Generally, the planarizing material layer 50 has a refractive index that is less than a refractive index of the filler material layer 48.

Accordingly, similarly as in the conventional configuration, the filler material layer 48 is made of a relatively high refractive index of typically at least 1.5 (e.g., 1.5-2.5). The materials used to form the bank structure 46 and filler material layer 48 may be the same or comparable as described above in connection with the conventional configuration. Again, the higher refractive index filler material layer 48 extracts more light from the emissive cavity 42 than if air were directly above the emissive cavity. The low refractive index planarizing material layer 50 is present over the filler material layer 48 to prevent optical crosstalk by preventing light from being coupled into a top or second glass substrate layer 52 that is disposed on the planarizing material layer, and then to the neighboring pixels.

In the exemplary embodiment of FIG. 3, the configuration and shape of the filler material layer 48 differs as compared to the analogous filler material layer 34 of the conventional configuration of FIG. 2. The filler material layer 48 includes a non-planar emitting side surface 54 opposite from the emissive cavity 42. A non-emitting side surface 56 of the filler material layer 48, i.e., the surface adjacent to the emissive cavity 42, remains a planar surface. Similarly, the top or second glass substrate 52 is planarizing, and thus the air/low refractive index layer 50 as described above also is planar at the surface of the second substrate 52.

In exemplary embodiments as depicted in FIG. 3, the non-planar emitting side surface 54 of the filler material layer 48 is shaped such that the filler material layer 48 includes a first region of positive curvature 58 and a second region of negative curvature 60 in a common cross sectional plane, and the curvatures are present in both orthogonal cross sectional planes. In other words, a positive curvature in this context is a curvature in a convex direction relative to the emissive cavity 42, and a negative curvature is a curvature in a concave direction relative to emissive cavity 42. In addition, the curvatures are present in the two dimensions that form the emitting surface of the pixel. In this example as depicted in FIG. 3, the second region of negative curvature 60 is located adjacent to the bank structure 46, and the first region of positive curvature 58 is located centrally relative to the second region of curvature 60.

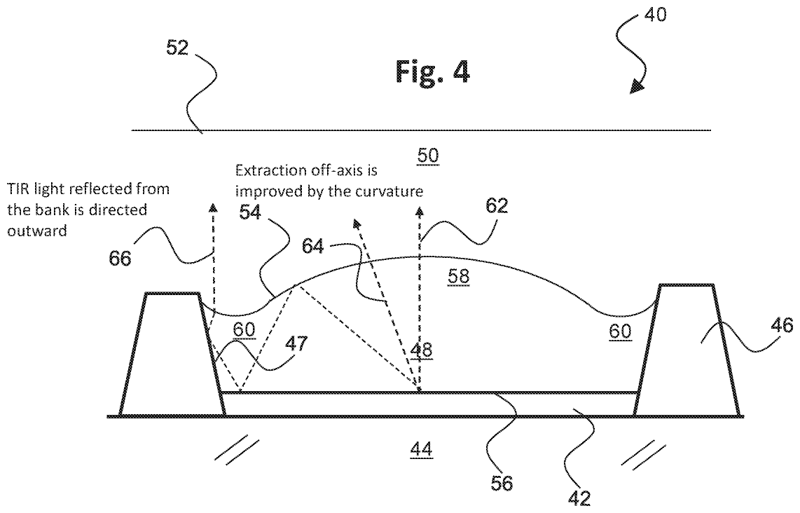

FIG. 4 is a drawing depicting the effect of the configuration of the filler material layer 48 of FIG. 3 on light emission from the light-emitting device 40. The configuration of the non-planar emitting side surface 54 operates to disrupt total internal reflection within the filler material layer 48. FIG. 4 depicts three exemplary light beams 62, 64, and 66 that are emitted from the emissive cavity 42 and into the filler material layer 48. Light beam 62 is illustrative of on-axis light, which is readily extracted as on-axis light that travels substantially normal to the emissive cavity in general is not affected by transmission through the emitting side surface of the filter material layer.

Light beam 64 is illustrative of off-axis light emitted from the emissive cavity 42 at a first angle, which in conventional configurations may undergo total internal reflection (TIR). The curvature of the first region of positive curvature 58 improves the extraction of the off-axis light 64 for enhanced extraction at wider emission angles. This occurs because due to the curvature of the first region 58, less light strikes the surface 54 at angles that would be subject to TIR, and thus there is enhanced light transmission of the angular distribution of light through the surface 54. In particular, due to the curvature of the surface of the first region 58, off-axis light meets the filler material surface along a majority of the emitting surface 54 at a smaller angle to the normal and thus with lower Fresnel losses. Light that undergoes total internal reflection thus is reduced insofar as a greater portion of the off-axis light propagates through the curved surface of the first region 58 for enhanced extraction. In this manner, the amount of light that is trapped by total internal reflection is reduced.

In addition, light beam 66 is illustrative of additional off-axis light emitted from the emissive cavity 42 at a second angle that corresponds to emission at a wider angle as compared to the first angle of the light beam 64. Because of the angle of incidence, light beam 66 undergoes an initial internal reflection at the surface 54, and is reflected back into the filler material layer 48 by the reflective electrode of the emissive cavity 42. In conventional configurations, such light, similarly as with other off-axis light, would be lost to TIR. As shown in FIG. 4, however, the light beam 66 is reflected off the bank structure 46 toward the second region of negative curvature 60. Due to the negative curvature of the second region 60, the light beam 66 is extracted through the surface 54 rather than undergoing additional internal reflection. Light that undergoes total internal reflection thus is further reduced insofar as a greater portion of the off-axis light that undergoes an initial internal reflection propagates through the curved surface of the second region 60 for enhanced extraction. In this manner, the amount of light that is trapped by total internal reflection further is reduced.

In the example of FIGS. 3 and 4, the first region of positive curvature 58 is centrally located relative to the second region of negative curvature 60, which is positioned adjacent to the bank structure 46. Similar performance may be achieved with the regions reversed, i.e., the second region of negative curvature 60 is centrally located relative to the first region of positive curvature 58 which is positioned adjacent to the bank structure 46. In addition, different types of curvature may be employed, including different spherical and aspherical curvatures. The curvature, for example, may include spherical micro-lens shapes, a facetted circle, aspherical micro-lens shapes, or a pyramid or prism shape.

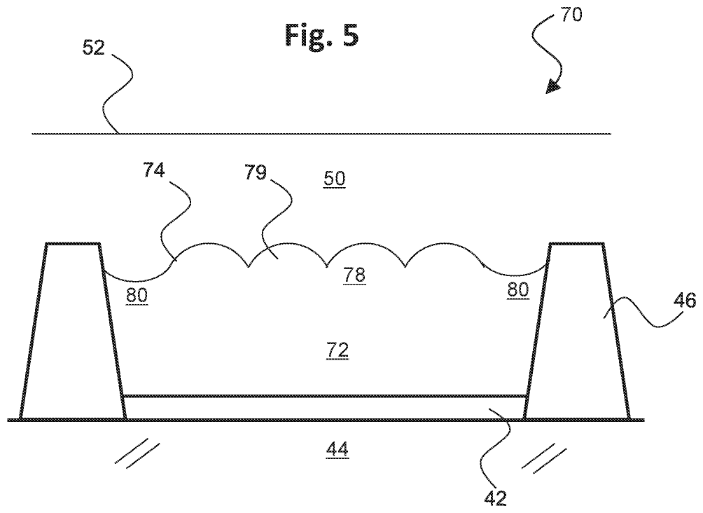

In the exemplary embodiment of FIGS. 3 and 4, the first region of positive curvature is configured as a single element of positive curvature in the region 58, but this also need not be the case. In other exemplary embodiments, the first region of positive curvature includes a plurality of positive curvature elements. FIG. 5 is a drawing depicting another exemplary light-emitting device structure 70 for a pixel in accordance with embodiments of the present application, using a micro-lens array as the region of positive curvature. Like components are identified with like reference numerals in FIG. 5 as in FIG. 3, with the principal difference being in the configuration of the first region of positive curvature. In this example, a filler material layer 72 includes a non-planar emitting side surface 74 shaped such that the filler material layer 72 includes a first region of positive curvature 78 that includes a plurality of repeating curved micro-lens elements 79. The emitting side surface 74 further is shaped such that the filler material layer 72 includes a second region of negative curvature 80 that is configured comparably as the second region 60 of the previous embodiment. Comparable effects on the light travel is achieved as in the previous embodiment.

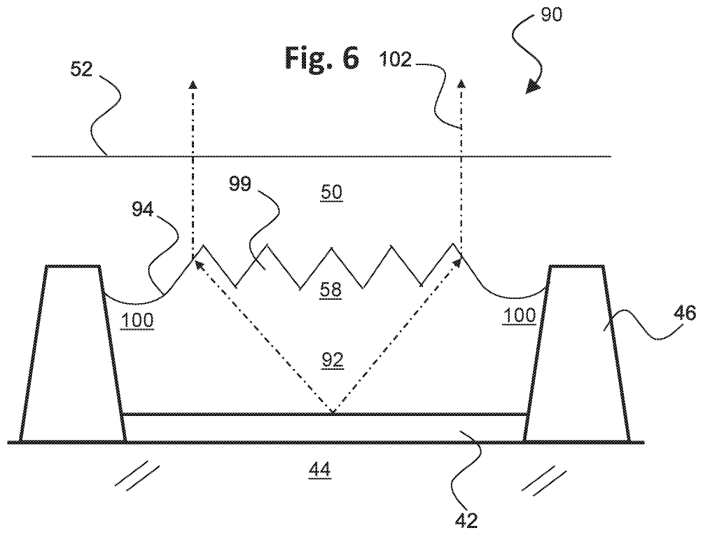

FIG. 6 is a drawing depicting another exemplary light-emitting device structure 90 for a pixel in accordance with embodiments of the present application, using a triangular prism array as the region of positive curvature. Like components are identified with like reference numerals in FIG. 6 as in FIG. 3, with the principal difference again being in the configuration of the first region of positive curvature. In this example, a filler material layer 92 includes a non-planar emitting side surface 94 that is shaped such that the filler material layer 92 includes a first region of positive curvature 98 that includes a plurality of repeating triangular prism elements 99. The emitting side surface 94 further is shaped such that the filler material layer 92 includes a second region of negative curvature 100 that is configured comparably as the second regions 60 and 80 of the previous embodiments. As shown by the light beam pathways 102 depicted in FIG. 6, this embodiment tends to be substantially effective at collimating the emitted light in addition to improving the light extraction as described above.

A top prism angle of substantially 90° provides the best collimation effect to provide enhanced on-axis brightness, although top prism angles of 90° up to about 160° may be suitable. At top prism angles below 90°, shadowing effects may occur. For example, with a filler material layer 92 of refractive index 1.8 into an air layer 50 and 90° prisms 99, emission from the emissive cavity 42 angled at 22° to normal in the filler material would experience refraction parallel with the normal and hence improve on-axis brightness. Pyramidal prism structures can be used for collimation in two dimensions, and elongated prism structures can be used for collimation from one direction for certain applications. The embodiment of FIG. 3 with a single element of positive curvature in the region 58 tends to provide better light extraction, although the embodiments of FIGS. 5 and 6 respectively having the micro-lens region 78 and the prism region 98 tend to be easier to manufacture.

An aspect of the invention, therefore, is a light-emitting device that has enhanced light output by shaping as non-planar an emitting side surface of the filler material layer to improve light extraction. In exemplary embodiments, the light-emitting device includes a bank structure; an emissive cavity disposed within the bank structure; and a filler material layer disposed within the bank structure and on a light-emitting side of the emissive cavity. An emitting side surface of the filler material layer opposite from the emissive cavity is a non-planar emitting side surface. The light-emitting device may include one or more of the following features, either individually or in combination.

In an exemplary embodiment of the light-emitting device, the emitting side surface is shaped such that the filler material includes a first region of positive curvature and a second region of negative curvature.

In an exemplary embodiment of the light-emitting device, the second region of negative curvature is located adjacent to the bank structure and the first region of positive curvature is located centrally relative to the second region of negative curvature.

In an exemplary embodiment of the light-emitting device, the first region of positive curvature is configured as a single element of positive curvature.

In an exemplary embodiment of the light-emitting device, the first region of positive curvature includes a plurality of positive curvature elements.

In an exemplary embodiment of the light-emitting device, the plurality of positive curvature elements comprises a micro-lens array having a plurality of curved lens elements.

In an exemplary embodiment of the light-emitting device, the plurality of positive curvature elements comprises a prism array having a plurality of triangular prism elements.

In an exemplary embodiment of the light-emitting device, a top prism angle of each of the plurality of triangular prism elements is from 90° to 160°.

In an exemplary embodiment of the light-emitting device, a non-emitting side surface of the filler material layer adjacent to the emissive cavity is a planar surface.

In an exemplary embodiment of the light-emitting device, the bank structure has a surface that faces the filler material layer that is specular reflective or light scattering.

In an exemplary embodiment of the light-emitting device, the filler material layer has a refractive index of at least 1.5.

In an exemplary embodiment of the light-emitting device, the filler material layer has a refractive index of 1.5 to 2.5.

In an exemplary embodiment of the light-emitting device, the emissive cavity is disposed on a substrate, and the emissive cavity is a top emitting device that emits light in a direction opposite from the substrate.

In an exemplary embodiment of the light-emitting device, the device further includes a planarizing material layer disposed on the filler material layer and that has a refractive index that is less than a refractive index of the filler material layer.

In an exemplary embodiment of the light-emitting device, the planarizing material layer has a refractive index between 1.0 and 1.2.

In an exemplary embodiment of the light-emitting device, the planarizing material layer is air.

In an exemplary embodiment of the light-emitting device, the device further incudes a top substrate disposed on the planarizing material layer.

In an exemplary embodiment of the light-emitting device, the emissive cavity includes a quantum dot emissive layer.

In an exemplary embodiment of the light-emitting device, the emissive cavity includes an organic emissive layer.

Although the invention has been shown and described with respect to a certain embodiment or embodiments, it is obvious that equivalent alterations and modifications will occur to others skilled in the art upon the reading and understanding of this specification and the annexed drawings. In particular regard to the various functions performed by the above described elements (components, assemblies, devices, compositions, etc.), the terms (including a reference to a “means”) used to describe such elements are intended to correspond, unless otherwise indicated, to any element which performs the specified function of the described element (i.e., that is functionally equivalent), even though not structurally equivalent to the disclosed structure which performs the function in the herein illustrated exemplary embodiment or embodiments of the invention. In addition, while a particular feature of the invention may have been described above with respect to only one or more of several illustrated embodiments, such feature may be combined with one or more other features of the other embodiments, as may be desired and advantageous for any given or particular application.

### INDUSTRIAL APPLICABILITY

The present invention relates to a layer structure used for light-emitting devices, such as for QLED and OLED displays. Hardware manufactured using this disclosure may be useful in a variety of fields that use such displays including gaming, entertainment, task support, medical, industrial design, navigation, transport, translation, education, and training.

### REFERENCE SIGNS LIST

10—conventional cavity structure
12—emissive layer
14—first charge transport layer (e.g., HTL)
16—second charge transport layer (e.g., ETL)
18—first electrode layer
20—second electrode layer
22—substrate
24—first HTL component layer
26—second HTL component layer
30—light emitting device structure
32—bank structure
34—filler material layer
36—bank structure inner surface
40—light emitting device structure
42—emissive cavity
44—substrate
46—bank structure
47—bank structure inner surface
48—filler material layer
50—planarizing material layer
52—top substrate
54—emitting side surface of filler material layer
56—non-emitting side surface of filler material layer
58—region of positive curvature
60—region of negative curvature
62—on-axis light beam
64—first angle off-axis light beam
66—second angle off-axis light beam
70—light emitting device structure
72—filler material layer
74—emitting side surface of filler material layer
78—region of positive curvature
79—micro-lens element
80—region of negative curvature
90—light emitting device structure
92—filler material layer
94—emitting side surface of filler material layer
98—region of positive curvature
99—prism element
100—region of negative curvature
102—light beam pathway

1. A light-emitting device comprising:
a bank structure;
an emissive cavity disposed within the bank structure; and
a filler material layer disposed within the bank structure and on a light-emitting side of the emissive cavity;
wherein an emitting side surface of the filler material layer opposite from the emissive cavity is a non-planar emitting side surface.

2. The light-emitting device of claim 1, wherein the emitting side surface is shaped such that the filler material includes a first region of positive curvature and a second region of negative curvature.

3. The light-emitting device of claim 2, wherein the second region of negative curvature is located adjacent to the bank structure and the first region of positive curvature is located centrally relative to the second region of negative curvature.

4. The light-emitting device of claim 2, wherein the first region of positive curvature is configured as a single element of positive curvature.

5. The light-emitting device of claim 2, wherein the first region of positive curvature includes a plurality of positive curvature elements.

6. The light-emitting device of claim 5, wherein the plurality of positive curvature elements comprises a micro-lens array having a plurality of curved lens elements.

7. The light-emitting device of claim 5, wherein the plurality of positive curvature elements comprises a prism array having a plurality of triangular prism elements.

8. The light-emitting device of claim 7, wherein a top prism angle of each of the plurality of triangular prism elements is from 90° to 160°.

9. The light-emitting device of claim 1, wherein a non-emitting side surface of the filler material layer adjacent to the emissive cavity is a planar surface.

10. The light-emitting device of claim 1, wherein the bank structure has a surface that faces the filler material layer that is specular reflective or light scattering.

11. The light-emitting device of claim 1, wherein the filler material layer has a refractive index of at least 1.5.

12. The light-emitting device of claim 1, wherein the filler material layer has a refractive index of 1.5 to 2.5.

13. The light-emitting device of claim 1, wherein the emissive cavity is disposed on a substrate, and the emissive cavity is a top emitting device that emits light in a direction opposite from the substrate.

14. The light emitting device of claim 1, further comprising a planarizing material layer disposed on the filler material layer and that has a refractive index that is less than a refractive index of the filler material layer.

15. The light-emitting device of claim 14, wherein the planarizing material layer has a refractive index between 1.0 and 1.2.

16. The light-emitting device of claim 14, wherein the planarizing material layer is air.

17. The light-emitting device of claim 14, further comprising a top substrate disposed on the planarizing material layer.

18. The light-emitting device of claim 1, wherein the emissive cavity includes a quantum dot emissive layer.

19. The light-emitting device of claim 1, wherein the emissive cavity includes an organic emissive layer.
